(19) United States
(12) Patent Application Publication
(10) Pub. No.: US 2005/0124087 A1
(43) Pub. Date: Jun. 9, 2005

(54) Method for manufacturing electro-optical device, electro-optical device, and electronic equipment

(75) Inventor: Kimitaka Kamijo, Shiojirishi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/985,887

(22) Filed: Nov. 12, 2004

(30) Foreign Application Priority Data
Nov. 28, 2003 (JP) 2003-399340

(51) Int. Cl. H01L 21/48; H01L 21/00; H01L 21/50

(52) U.S. Cl. 438/29; 438/24; 438/25; 438/22

(57) ABSTRACT

Exemplary embodiments of the present invention make it possible to ensure an actual aperture ratio with respect to an electro-optical device provided with an active element, and to manufacture with ease. A method for manufacturing an electro-optical device of exemplary embodiments of the present invention includes forming an active element on one substrate, as an element formation; forming an insulating layer on one substrate provided with the active element, the insulating layer having an aperture reaching a conductive junction of the active element, as an insulating layer formation; forming an asperity shape through transfer on the surface of the insulating layer by pressing a mold against the insulating layer having the aperture, as an asperity formation; and forming a reflection layer on the insulating layer in order to provide a scattering reflection surface incorporating the asperity shape and, in addition, conductive-connecting an electrode constructed by the reflection layer or constructed separately from the reflection layer to the active element directly or indirectly via the aperture, as an upper layer processing.

### BACKGROUND

Exemplary embodiments of the present invention relate to a method for manufacturing an electro-optical device, an electro-optical device, and electronic equipment. In particular, exemplary embodiments relate to a method for manufacturing an electro-optical device provided with a reflection layer to reflect the light incident from the outside, and relate to a structure corresponding thereto.

The related art includes reflective liquid crystal display devices or transflective liquid crystal display devices used for display portions of portable data terminals, e.g., mobile phone/cellular phone and PDA (Personal Digital Assistance), in order to reduce the power consumption. These reflective liquid crystal display devices are provided with reflection layers to reflect the light incident from the display surface side so as to perform display. The transflective liquid crystal display device is provided with a window, which becomes a light-transmission region, on the above-described reflection layer, so that reflective display and transmissive display can be performed. In general, a scattering reflection surface provided with many fine asperities is formed on the surface of this reflection layer. When the scattering reflection surface is disposed on the surface of the reflection layer, as described above, since the external light is scattered and the direction of reflection is decentralized, the amount of reflected light in the direction of the line of sight can be increased compared with that in the case where the surface of the reflection layer is formed to become a flat mirror surface. Consequently, the display can become well-lit and, in addition, the dazzling due to illumination light, shown through the background, and the like can be reduced or prevented.

The scattering reflection surface of the above-described reflection layer is formed by various related art methods. In general, examples of the methods include a method in which a fine asperity shape is formed on the surface of a substrate by etching or the like, a metal thin film made of Al or the like is formed thereon, so as to form a reflection surface incorporating the asperity shape on the substrate surface. A method in which a photosensitive resin is applied on the surface of a substrate, a fine surface asperity shape is formed on the insulating layer through photolithography for performing exposure and development of the resulting photosensitive resin by the use of a predetermined mask, and a metal thin film is formed thereon, so as to form a reflection surface incorporating the above-described surface asperity shape. Additionally a method in which a fine surface asperity shape is formed on the insulating layer on a substrate through, for example, photolithography similar to that described above, the insulating layer is heated to be softened in order that the surface asperity shape is made to become a smooth shape and, thereafter, a metal thin film is formed thereon, so as to form a reflection surface incorporating the above-described surface asperity shape.

However, with respect to the method in which the surface of the above-described substrate is etched and the method in which the insulating layer provided with the surface asperity shape is formed through photolithography, the asperity shape of the scattering reflection surface of the reflection layer significantly fluctuates in accordance with the circumstances of the etching and the photolithography and, thereby, the controllability of the light reflection property of the scattering reflection surface is not always good. Consequently, it is difficult to address or achieve the scattering property suitable for the above-described scattering reflection surface, and there is a problem of low reproducibility thereof as well.

In consideration of the above-described circumstances, related art documents Japanese Unexamined Patent Application Publication No. 10-232303 and Japanese Unexamined Patent Application Publication No. 2002-23181 disclose a method for manufacturing a reflection plate, in which an insulating layer is applied to a substrate and, thereafter, a mold having a predetermined shape of asperity surface is pressed against the above-described insulating layer so as to transfer the asperity surface of the above-described mold to the surface of the above-described insulating layer.

Related art document Japanese Unexamined Patent Application Publication No. 10-232303 describes a method in which a photosensitive insulating layer is applied to a substrate, a mold having an asperity surface is pressed against the resulting photosensitive insulating layer, light is applied under this condition to effect curing, so that an insulating layer provided with the asperity surface is formed and, thereafter, a reflection layer is formed on the asperity surface of this insulating layer.

Related art document Japanese Unexamined Patent Application Publication No. 2002-23181 describes a method in which a mold provided with a predetermined asperity surface on a portion where a reflection pixel electrode is to be formed and provided with a flat surface on the other portion is pressed against the surface of an insulating resin substrate to form an asperity surface portion and a flat surface portion, a reflection layer is formed on the resulting asperity surface, and an active element and wirings are formed on the flat surface portion.

### SUMMARY

However, with respect to the above-described related art methods, it is predicted that various problems occur in construction of an electro-optical device provided with an active element. For example, in the method described in related art document Japanese Unexamined Patent Application Publication No. 10-232303, since the insulating layer is formed by applying the light to effect the curing while the mold is pressed against the uncured photosensitive insulating layer, the active element must be formed as a layer on the insulating layer as in disclosed in related art document Japanese Unexamined Patent Application Publication No. 2002-23181, or a contact hole must be formed in the insulating layer in order to conductive-connect the active element formed as a layer under the insulating layer to the pixel electrode.

In this case, when the active element is formed as the layer on the insulating layer, as in the former, since any scattering reflection surface cannot be formed in the active element formation region, there is a problem in that the aperture ratio is decreased and the display is darkened. In particular, when a TFT (thin film transistor) is used as the active element, a storage capacitor is simultaneously disposed in many cases. Since the scattering reflection surface cannot be formed in the storage capacitor formation region as well, the actual aperture ratio becomes smaller and, therefore, the display becomes even more darkened. With respect to the transflective liquid crystal display device having above-described structure, since a transmission region must be disposed in a pixel, the area of the scattering reflection surface becomes further smaller. Consequently, it becomes very difficult to ensure the brightness of the reflective display.

On the other hand, in the latter case, it is very difficult to form a contact hole in the insulating layer after being cured in terms of manufacture, and there are problems in that the number of steps is increased, and the manufacturing cost is increased.

exemplary embodiments of the present invention address the above-described and/or other problems. Accordingly, the object of exemplary embodiments of the present invention is to provide a method and a device structure, wherein an actual aperture ratio can be ensured in an electro-optical device provided with an active element and the manufacture can be performed with ease.

In order to address the above-described and/or other problems, a method for manufacturing an electro-optical device, according to exemplary embodiments of the present invention, is the method for manufacturing an electro-optical device in which a pair of substrates are disposed facing each other with an electro-optical layer therebetween. An active element and a reflection layer are provided on one substrate of the above-described pair of substrates. The method includes the steps of forming the above-described active element on the above-described one substrate, as an element formation; forming an insulating layer on the above-described one substrate provided with the above-described active element, the insulating layer having an aperture reaching a conductive junction of the above-described active element, as an insulating layer formation; forming an asperity shape through transfer on the surface of the above-described insulating layer by pressing a mold against the above-described insulating layer having the above-described aperture, as an asperity formation; and forming the above-described reflection layer on the above-described insulating layer in order that a scattering reflection surface incorporating the above-described asperity shape is provided and, in addition, conductive-connecting an electrode constructed by the above-described reflection layer or constructed separately from the above-described reflection layer to the above-described active element directly or indirectly via the above-described aperture, as an upper layer processing.

According to exemplary embodiments of the present invention, the active element is formed and, thereafter, the insulating layer having an aperture reaching the conductive junction of the active element is formed, so that since the scattering reflection surface can be formed in the region superposed on the active element, when viewed from above, the actual aperture ratio can be increased, and a well-lit display can be addressed or achieved. Since the insulating layer having the aperture is formed and, thereafter, the asperity shape is formed on the surface of the insulating layer, the aperture to conductive-connect the active element and the electrode can be readily formed in the insulating layer. Furthermore, the mold is pressed against the insulating layer, the asperity shape is transferred to the surface of the insulating layer and, thereby, the scattering reflection surface of the reflection layer can be formed with excellent controllability. Consequently, the viewability can be further enhanced.

The electrode conductive-connected to the active element via the aperture may be constructed as a reflection electrode by the above-described reflection layer or be constructed separately from the reflection layer. In the latter case, the electrode may be conductive-connected to the active element via the reflection layer. Preferably, the electrode is formed from a transparent electrode. For example, the transparent electrode is formed over the entire pixel and, in addition, a transmission region where no reflection layer is formed is disposed in a part of the pixel, so that a transflective electro-optical device can be constructed.

In exemplary embodiments of the present invention, preferably, a protrusion to be inserted into the above-described aperture is disposed on the mold surface of the mold, at the location corresponding to the above-described aperture. In this manner, in the asperity transfer since a transfer pressure is applied to the insulating layer while the above-described protrusion is inserted in the aperture, crushing of the aperture due to pressurization of the insulating layer can be reduced and/or prevented. Here, it is desirable that the end of the above-described protrusion is configured not to contact the active element during the transfer. Specifically, with respect to the protrusion, desirably, the amount of protrusion is smaller than the depth of the aperture of the insulating layer. In this manner, it is reduced or prevented that the protrusion is brought into contact with the active element so as to damage the active element during the asperity transfer. It is significant only that the protrusion is configured to be capable of at least supporting the aperture edge and, in particular, it is desirable that the protrusion is configured to be brought into contact with the entire aperture edge during the transfer.

In exemplary embodiments of the present invention, preferably, a concave portion lower than the surrounding is disposed on the mold surface of the above-described mold, at the location corresponding to the above-described active element. In this manner, the transfer pressure applied to the active element during the asperity transfer can be reduced and, therefore, the active element is reduced or prevented from being damaged. Here, it is desirable that a concave portion lower than the surrounding is also disposed in the plane region corresponding to the wiring connected to the active element. In this manner, the transfer pressure applied to the wiring can also be reduced and, thereby, break defect in the wiring and the like can be reduced or prevented as well.

In exemplary embodiments of the present invention, preferably, the above-described aperture is disposed in order that at least a portion of the above-described active element is exposed, the portion performing the switching function (for example, a channel region and a MIM junction region). In this manner, the aperture is disposed in order that at least a portion of the active element is exposed, the portion performing the switching function, and thereby, the transfer pressure is not applied to the portion to perform the switching function during the asperity transfer, so that the active element can be reduced or prevented from being damaged. Here, the above-described aperture may be formed to expose the entire active element.

In exemplary embodiments of the present invention, preferably, a transmission region not provided with the above-described reflection layer is disposed, and the above-described aperture includes a portion formed corresponding to the above-described transmission region. In this manner, since the aperture of the insulating layer includes the portion formed corresponding to the transmission region, no insulating layer is present in the transmission region. Consequently, the light transmittance ratio of the transmission region can be increased and, in addition, a coloring material or a light-shield material can be used for the insulating layer as well. Therefore, the flexibility in selection of the material for the insulating layer is increased. Since the insulating layer is used as the light-shield layer, a light-shield pattern to reduce or prevent the light from entering the active element is not necessarily formed separately. Furthermore, in the case where the electro-optical device is a liquid crystal display device, it becomes possible to adopt a multi-gap structure, described below, through the use of the height difference of the insulating layer and, therefore, a higher performance transflective liquid crystal display device can be constructed.

In exemplary embodiments of the present invention, preferably, the above-described upper layer processing includes a sub-step of forming the above-described reflection layer on the above-described insulating layer and a sub-step of forming the above-described electrode as a layer on or under the above-described reflection layer, the electrode at least overlapping the reflection layer. In this manner, the scattering reflection surface incorporating the asperity shape of the insulating layer can readily be formed and, in addition, the reflection layer and the electrode can be mutually conductive-connected. When a transmission region provided with an electrode but provided with no reflection layer is constructed, a transflective electro-optical device can be constructed.

In exemplary embodiments of the present invention, the above-described insulating layer formation sequentially includes applying a photosensitive resin, of exposing the photosensitive resin, and of developing the above-described photosensitive resin to form the above-described aperture. In this manner, the insulating layer having the aperture can be very readily formed by usual photolithographic technology. In this case, it is desirable that the above-described asperity transfer is performed and, thereafter, the photosensitive resin is subjected to a heat treatment so as to be cured. In this manner, the transfer property can be ensured during the asperity transfer by treating the photosensitive resin in the condition in which the plastic deformation can be performed to some extent and, in addition, after the asperity transfer is performed, the insulating layer can be provided with an appropriate hardness by being subjected to a heat treatment.

An electro-optical device of exemplary embodiments of the present invention is the electro-optical device in which a pair of substrates are disposed facing each other with an electro-optical layer therebetween and an active element and a reflection layer are provided on one substrate of the above-described pair of substrates. An insulating layer has an aperture is disposed between the above-described active element and the above-described reflection layer. The above-described insulating layer has a surface asperity shape transferred by a mold being pressed against the above-described insulating layer, the above-described reflection layer is provided with a scattering reflection surface incorporating the above-described surface asperity shape, and an electrode constructed by the above-described reflection layer or constructed separately from the above-described reflection layer is conductive-connected to a conductive junction of the above-described active element directly or indirectly via the above-described aperture.

According to exemplary embodiments of the present invention, the insulating layer having the aperture reaching the conductive junction of the active element is formed between the active element and the reflection layer and, thereby, the scattering reflection surface can also be formed in the region superposed on the active element, when viewed from above, so that the actual aperture ratio can be increased, and the well-lit display can be addressed or achieved. Furthermore, the mold is pressed against the insulating layer, the asperity shape is transferred to the surface of the insulating layer and, thereby, the surface asperity shape of the insulating layer is formed. Consequently, the controllability of the scattering reflection surface of the reflection layer can be enhanced, so that the viewability can be further enhanced.

In exemplary embodiments of the present invention, preferably, the above-described aperture is disposed in order that at least a portion of the above-described active element is exposed, the portion performing the switching function. When the aperture is disposed in order that at least a portion of the active element is exposed, the portion performing the switching function, as described above, the transfer pressure is not applied to the portion to perform the switching function during the asperity transfer, so that the active element can be reduced or prevented from being damaged. Here, the above-described aperture may be formed to expose the entire active element.

In exemplary embodiments of the present invention, preferably, a transmission region not provided with the above-described reflection layer is disposed, and the above-described aperture includes a portion formed corresponding to the above-described transmission region. In this manner, since the aperture of the insulating layer includes the portion formed corresponding to the transmission region, no insulating layer is present in the transmission region. Consequently, the light transmittance ratio of the transmission region can be increased and, in addition, a coloring material or a light-shield material can be used for the insulating layer as well. Therefore, the flexibility in selection of the material for the insulating layer is increased. Since the insulating layer is used as the light-shield layer, a light-shield pattern to reduce or prevent the light from entering the active element is not necessarily formed separately. Furthermore, in the case where the electro-optical device is a liquid crystal display device, it becomes possible to adopt a multi-gap structure, described below, through the use of the height difference of the insulating layer and, therefore, a higher performance transflective liquid crystal display device can be constructed.

Electronic equipment of exemplary embodiments of the present invention is provided with any one of the above-described electro-optical devices in a display portion. Examples of the electronic equipment include image display devices, e.g., various monitors, mobile phones, and computer equipment. In particular, mobile communications equipment, e.g., mobile phones, and other mobile information equipment are preferable. In general, the above-described equipment is provided with a control device (for example, a display control system) to control the electro-optical device, as described below.

### BRIEF DESCRIPTION OF THE DRAWINGS

FIG. 1 is a magnified partial sectional view schematically showing the magnified structure of the liquid crystal display device in the first exemplary embodiment;

FIGS. 2(a) and 2(b) are magnified partial layout schematic plan views showing a part of the first exemplary embodiment under magnification;

FIGS. 3(a) to 3(d) are schematic sectional views of the steps, showing the manufacturing process of the element substrate in the first exemplary embodiment;

FIGS. 4(a) to 4(c) are schematic sectional views of the steps, showing the manufacturing process of the element substrate in the first exemplary embodiment;

FIG. 5(a) is a magnified schematic partial sectional view showing the liquid crystal display device in the second exemplary embodiment, and FIG. 5(b) is a schematic magnified partial layout plan;

FIGS. 6(a) to 6(c) are schematic sectional views of the steps, showing the manufacturing process of the element substrate in the third exemplary embodiment;

FIGS. 7(a) and 7(b) are schematic sectional views of the steps, showing the manufacturing process of the element substrate in the third exemplary embodiment;

FIG. 8(a) is a schematic configuration diagram of the fourth exemplary embodiment, FIGS. 8(b) and 8(c) are schematic sectional views of the steps, showing the manufacturing process of the element substrate, and FIGS. 8(d) and 8(e) are schematic plan views showing the steps;

FIG. 9(a) to 9(c) are schematic sectional views of the steps, showing the manufacturing process of the element substrate in the fourth exemplary embodiment, and FIGS. 9(d) and 9(e) are schematic plan views showing the steps;

FIG. 10 is a schematic configuration diagram showing the display control system of the fifth exemplary embodiment;

FIG. 11 is a schematic perspective view showing the appearance of the fifth exemplary embodiment.

### DETAILED DESCRIPTION OF EMBODIMENTS

The exemplary embodiments of the present invention will be described below in detail with reference to the attached drawings. In each exemplary embodiment described below, an example constructed as a liquid crystal display device is shown. However, exemplary embodiments of the present invention are not limited to liquid crystal display devices, and exemplary embodiments of the present invention can be similarly applied to various electro-optical devices, for example, electroluminescence devices, organic electroluminescence devices, plasma display devices, electrophoresis display devices, and devices through the use of electron emission elements (Field Emission Display, Surface-Conduction Electron-Emitter Display, and the like).

### FIRST EXEMPLARY EMBODIMENT

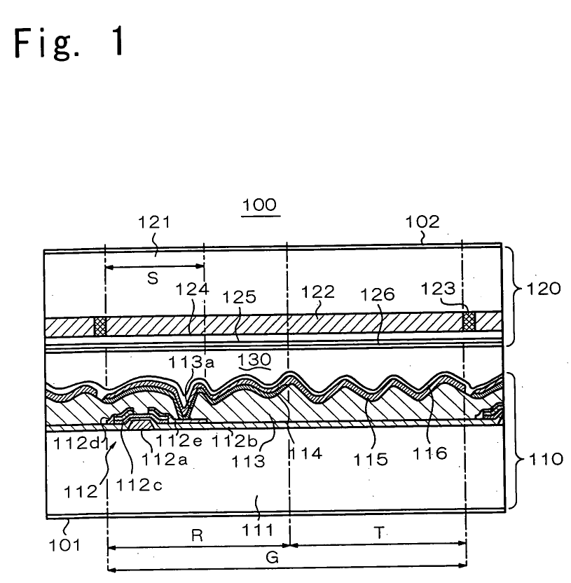

FIG. 1 is a magnified partial vertical schematic sectional view showing the rough configuration of the panel structure of an electro-optical device in the first exemplary embodiment according to the present invention. The present exemplary embodiment is a transflective liquid crystal display device 100, and a liquid crystal 130 as an electro-optic material, is disposed between a element substrate 110 and a facing-substrate 120. The element substrate 110 and the facing-substrate 120 are fixed by adhesion with a sealing component therebetween, although not shown in the drawing, while a spacing is ensured between them. Polarizers 101 and 102 are disposed on the outer surfaces of the element substrate 110 and the facing-substrate 120 in order that the polarization axes mutually satisfy a predetermined positional relationship (for example, cross Nicol arrangement).

The element substrate 110 is provided with a TFT (Thin Film Transistor) 112 formed as an active element on the surface of a substrate 111 composed of glass, plastic, or the like, an insulating layer 113 formed on the substrate 111 and the TFT 112, a reflection layer 114 formed on the insulating layer 113, and a transparent electrode 115 formed on the reflection layer 114. An alignment layer 116 composed of a glancing angle deposition film, a polyimide resin, or the like is formed on the transparent electrode 115.

The TFT 112 includes a gate 112a conductive-connected to a scanning line, an insulating thin film 112b formed from SiO₂ or the like on this gate 112a, a semiconductor layer 112c composed of amorphous silicon or the like and disposed facing the gate 112a with the insulating thin film 12b therebetween, a source electrode 112d conductive-connected to a data line and the semiconductor layer 112c, and a drain electrode 112e conductive-connected to the semiconductor layer 112c.

The insulating layer 113 formed on the TFT 112 can be composed of, for example, a resin raw material, e.g., an acrylic resin or a silicon resin, or an inorganic raw material, e.g., silicon oxide, silicon nitride, or silicate glass. This insulating layer 113 has an aperture 113a. The above-described drain electrode 112e is conductive-connected to the above-described reflection layer 114 and the transparent electrode 115 via this aperture 113a.

The surface of the insulating layer 113 has a fine asperity shape. The surface asperity shape of this insulating layer is made by transfer through the use of a predetermined mold, as described below. When the asperity shape is thus transferred through the use of a mold, the tilt angle distribution, the curved surface, the depths of asperities, and the like of the surface asperity shape, can be addressed or achieved precisely with excellent reproducibility.

The reflection layer 114 is composed of a metal thin film of Al, an Al alloy, Ag, a Ag alloy, or the like. The reflection layer 114 is formed on the surface asperity shape of the above-described insulating layer 113 and, thereby is provided with a scattering reflection surface incorporating the above-described surface asperity shape. The reflection layer 114 is conductive-connected to the drain electrode 112e serving as a conductive junction of the above-described TFT 112 via the aperture 113a of the insulating layer 113. In the example shown in the drawing, a reflection region R and a transmission region T are disposed in a pixel G, while the optical state of the pixel can be independently controlled. In this case, the reflection layer 114 is formed in the reflection region R, and is not formed in the transmission region T.

The transparent electrode 115 is composed of a transparent conductor, e.g., ITO (indium tin oxide), tin oxide, or the like. The transparent electrode 115 is formed on the insulating layer 113 and the reflection layer 114. In the example shown in the drawing, the transparent electrode 115 is formed on the entire region of the pixel G. The transparent electrode 115 is conductive-connected to the above-described reflection layer 114 and, thereby, is conductive-connected indirectly to the conductive junction of the TFT 112 (drain electrode 112e).

On the other hand, a substrate 121 composed of glass or plastic, a coloring filter 122 formed on the inner surface of the substrate 121, light-shield portions 123 formed in the regions between the pixels, a protective film 124 formed on the coloring filter 122 and the light-shield portions, and a transparent electrode 125 formed on the protective film 124, are disposed on the facing-substrate 120. The coloring filter 122, light-shield portions 123, and the protective film 124 constitute a color filter. An alignment layer 126 composed of a glancing angle deposition film, a polyimide resin, or the like is formed on the transparent electrode 125.

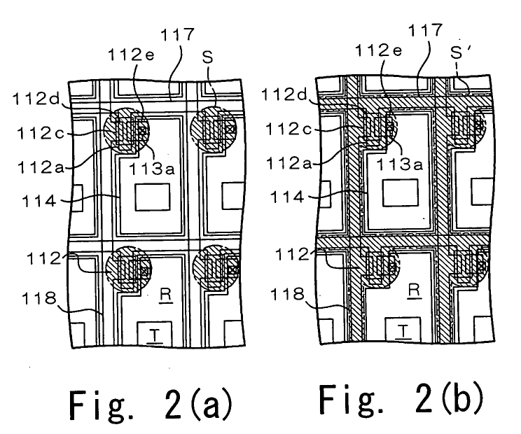

FIG. 2(a) is a magnified partial layout schematic plan view showing an example of the two-dimensional structure in the present exemplary embodiment. In the present exemplary embodiment, the configuration of the surface asperity shape of the insulating layer 113 and the scattering reflection surface of the reflection layer 114 in an element formation region S (the range thereof is indicated by arrows in FIG. 1 and by hatch patterns in FIG. 2(a)) in which the TFT 112 is formed, is different from the configuration in the surface region other than this element formation region S. That is, in the element formation region S, the surfaces of the insulating layer 113 and the reflection layer 114 are constructed to become convex in order to be somewhat protruded from the surrounding. In the element formation region S, a fine asperity shape is hardly formed in contrast to the surface region other than that. An asperity shape may be constructed in the element formation region S. In this case, the asperity shape in the element formation region S is formed in order that the level of the bottom thereof becomes higher than the level of the bottom of the fine asperity shape formed in the other surface region. This is a result of constructing the mold surface in order that the transfer pressure applied to the element formation region S is made lower than the pressure applied to the surrounding surface region when the asperity shape is transferred to the surface of the insulating layer 113 by the mold, as described below. In this manner, the TFT 112 can be reduced or prevented from being damaged or broken. The surface configuration of the above-described element formation region S may be formed in at least a portion of the TFT 112, the portion performing the switching operation, for example, in only a channel region of the semiconductor layer 112c (the portion at which the semiconductor layer 112c and the gate 112a overlap one another when viewed from above). In this manner, the effect of the transfer pressure can be reduced to the level at which the switching operation of the TFT 112 is not affected or lower.

As shown in FIGS. 2(a)-(b) scanning lines 117 and data lines 118 connected to the TFT 112 are formed on the element substrate 120 of the present exemplary embodiment. In this case, not only the element formation regions S shown in FIG. 2(a), but an electric field application structure region S′ including furthermore a wiring formation region provided with the scanning lines 117 and the data lines 118 shown in FIG. 2(b), may have the surface configuration similar to that of the above-described element formation regions S. In this case, wiring defect due to the above-described transfer pressure (break, increase in wiring resistance, and the like) can be reduced or prevented as well.

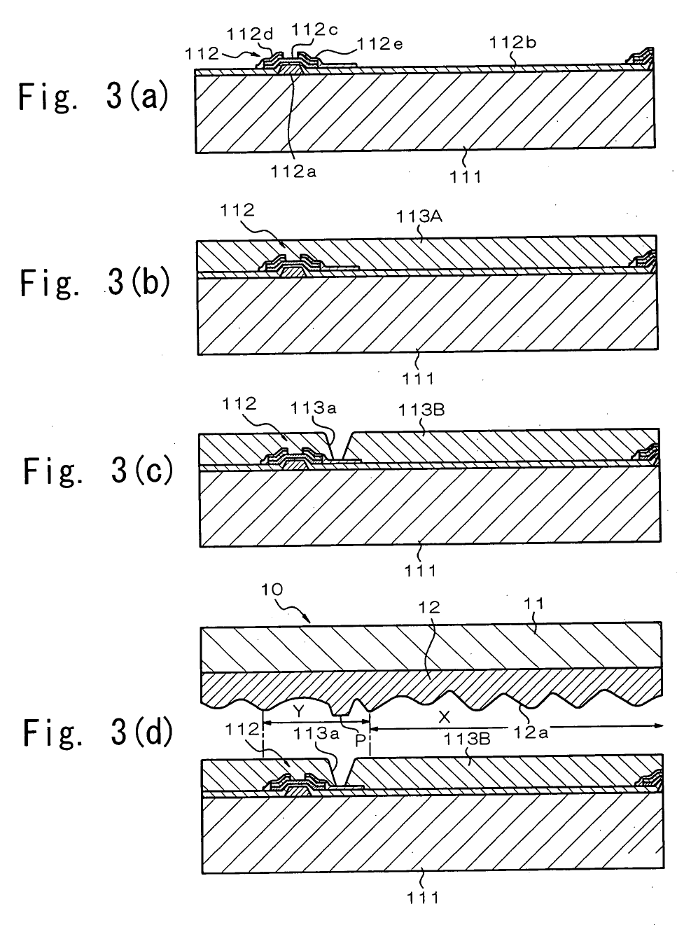

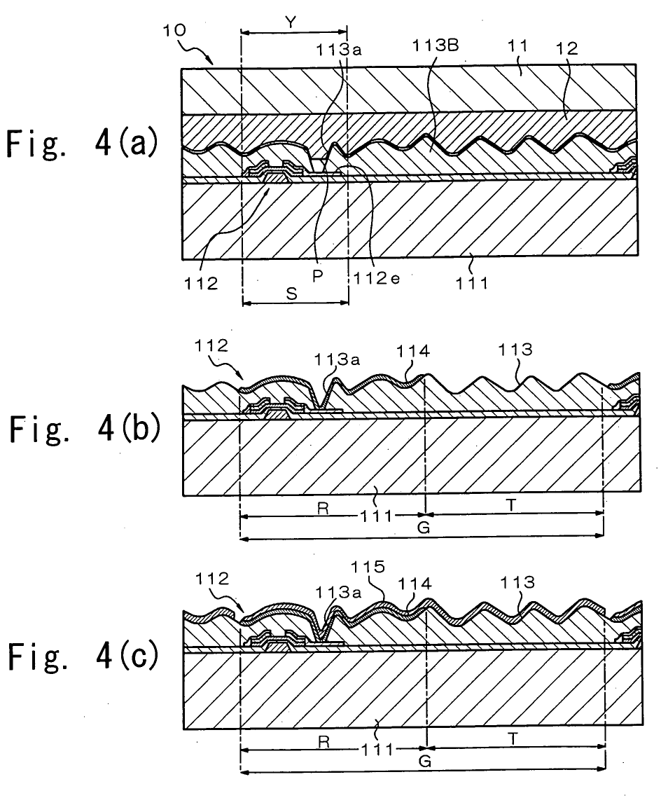

A method for manufacturing the above-described liquid crystal display device 100 will be described below with reference to FIG. 3 and FIG. 4. FIG. 3 and FIG. 4 are schematic sectional views of steps showing the manufacturing process of the element substrate 110 of the above-described liquid crystal display device 100. Initially, as shown in FIG. 3(a), the TFT 112 is formed on the inner surface of the substrate 111 (element formation). Here, an insulating film may be formed between the substrate 111 and the TFT 112 in order to enhance the adhesion. The TFT 112 is formed as described below, for example. The gate 112a is formed together with the scanning line, although not shown in the drawing. An insulating thin film 112 is formed thereon from SiO₂ or the like and, thereafter, the semiconductor layer 112c is formed from amorphous silicon or the like. Finally, the source electrode 112d and the drain electrode 112e are formed together with the data line, although not shown in the drawing. In each of the above-described steps, a vapor deposition method, a sputtering method, a CVD method or the like is used as a means of film formation, and after the film is formed, patterning is performed appropriately by photolithography.

An uncured photosensitive resin 113A is applied to the substrate 111 and the TFT 112 by a spin coating method, a roll coating method, or the like. If necessary, the resulting photosensitive resin 113A is dried by vacuum drying or the like, and furthermore, if necessary, pre-baking is performed, for example, at about 60° C. to 100° C. for about 30 minutes. Thereafter, a light source in accordance with the photosensitivity of the photosensitive resin is used, and an exposure treatment at about 150 mJ/cm², for example, is performed by the use of a predetermined mask. Development is performed with an inorganic alkaline solution or the like and, thereby, as shown in FIG. 3(c), an insulating layer 113B having an aperture 113a is formed (insulating layer formation).

Here, in the forming the aperture 113a in the insulating layer 113 during this insulating layer formation, preferably, the insulating layer 113 disposed in the area other than the display area is removed simultaneously. In this manner, when the element substrate 110 and the facing-substrate 120 are bonded together with a sealing component therebetween, the mechanical strength (adhesion between the sealing component and the substrate) of the sealing portion can be increased without increasing the number of man-hours.

A mold 10 shown in FIG. 3(d) is pressed against the insulating layer 113B (asperity transfer). This mold 10 is provided with a mold surface 12a having a fine asperity surface. Specifically, the mold 10 includes a mold material 12 on a base 11, and the mold material 12 is provided with the above-described mold surface 12a having a predetermined surface asperity shape. The mold material 12 is formed by, for example, transferring the surface asperity shape from a master provided with a surface substantially corresponding to the scattering reflection surface to be produced finally. The mold material 12 can be composed of a synthetic resin, a metal, or the like.

The mold surface 12a is provided with a protrusion P at the location corresponding to the aperture 113a of the above-described insulating layer 113B. This protrusion P is to support the aperture 113a in order that the aperture 113a is not crushed during the transfer by the use of the mold 10. That is, as shown in FIG. 4(a), when the mold 10 is pressed against the insulating layer 113B, the protrusion P is inserted into the aperture 113a and, thereby, a state in which the protrusion P supports the inner surface of the aperture 113a from the inside is brought about. Therefore, when the mold 10 is pressed against the insulating layer 113B and the transfer pressure is applied to the insulating layer 113B, it can be reduced or prevented that the aperture 113a is crushed and the range of aperture constructed by the aperture 113a of the insulating layer 113 is reduced.

Here, the amount (height) of protrusion of the protrusion P is constructed to become smaller than the depth of the aperture 113a during the transfer. That is, the protrusion P is constructed in order that the end thereof is not brought into contact with the conductive junction (drain electrode 112e) of the active element (TFT 112) exposed due to the aperture 113a during the transfer. Therefore, the conductive junction of the active element can be reduced or prevented from being damaged by the protrusion P during the asperity transfer.

The description will be made with reference to FIG. 3(d). The mold surface 12a is provided with an asperity surface portion X having a fine asperity shape corresponding to the surface shape of the scattering reflection surface to be formed on the reflection layer 114 and an avoidance surface portion Y dented to become somewhat concave compared with this asperity surface portion X. On the asperity surface portion X, a fine asperity shape is arranged randomly and two-dimensionally, for example. The surface configuration of the asperity surface portion X is different from the surface configuration of the avoidance surface portion Y. This avoidance surface portion Y is disposed corresponding to the element formation region S or the electric field application structure region S′ in the above-described exemplary embodiment (that is, in order that the location and the range agree during the transfer). The avoidance surface portion Y may be constructed to become concave as a whole, or be constructed in order that although a fine asperity shape is provided, the height of the crest of the asperity shape or the average height of the asperity shape becomes lower than the height of the crest of the surrounding asperity shape or the average height of the surrounding asperity shape.

When the avoidance surface portion Y is provided with the above-described protrusion P, the portion other than the protrusion P is constructed as described above. This is because even when the protrusion P is disposed in the avoidance surface portion Y, since the protrusion P is arranged at the location corresponding to the aperture 113a of the insulating layer 113, the transfer pressure is not applied to the insulating layer 113 due to the protrusion P.

In the asperity transfer shown in FIG. 4(a), the avoidance surface portion Y is lower than the surrounding asperity surface portion X and, thereby, the transfer pressure applied to the element formation region S corresponding to this avoidance surface portion Y becomes lower than the transfer pressure applied to the surrounding region. Consequently, the pressure applied to the active element (TFT 112) is reduced and, thereby, occurrence of damage and other defects in the active element can be suppressed. In the case where the avoidance surface portion Y is disposed corresponding to the electric field application structure region S′, occurrence of defect in not only the active element, but also the wirings (scanning line and data line) can be reduced as well.

The above-described mold 10 is peeled off the insulating layer 113B. In order to enhance the mold release property at this time, a coating layer may be formed beforehand on the mold surface 12a of the above-described mold 10, or the above-described asperity transfer may be performed while an appropriate mold release agent is interposed between the mold surface 12a and the insulating layer 113B. When the mold 10 is peeled off in this manner, the surface shape of the mold surface 12a is transferred, as described above, and thereby, the asperity shape is formed on the surface of the insulating layer. Subsequently, if necessary, the insulating layer 113B is fired (post-baked), and finally, the insulating layer 113B having a desired hardness is formed as shown in FIG. 4(b). In this firing, for example, a heat treatment (a treatment preferably at a temperature higher than that in the above-described pre-baking) is performed at 200° C. to 250° C. for about 30 minutes.

As shown in FIG. 4(b), the reflection layer 114 is formed on the insulating layer 113. The reflection layer 114 is formed by a film formation method, e.g., a vapor deposition method or a sputtering method. In the present exemplary embodiment, the reflection layer 114 is constructed to have a pattern separated on a pixel G basis. More specifically, the reflection layer 114 is formed only within the reflection region R in the pixel G, and is not formed in the transmission region T. Such a pattern of the reflection layer 114 is formed by performing an appropriate etching treatment (for example, wet etching).

As shown in FIG. 4(c), the transparent electrode 115 composed of a transparent conductor, e.g., ITO, is formed on the insulating layer 113 and the reflection layer 114. The film of this transparent electrode 115 can be formed by a sputtering method. This transparent electrode 115 is formed to have patterns mutually independent on a pixel G basis. The transparent electrode 115 is formed almost all over the pixel G (that is, in both the reflection region R and the transmission region T).

Another metal film may be interposed between the above-described reflection layer 114 and the transparent electrode 115. The transparent electrode 115 is not necessarily formed all over the reflection layer 114, as long as the transparent electrode 115 is conductive-connected to the reflection layer 114 to such an extent that the driving of the electro-optical material (liquid crystal 130) is not hindered.

### SECOND EXEMPLARY EMBODIMENT

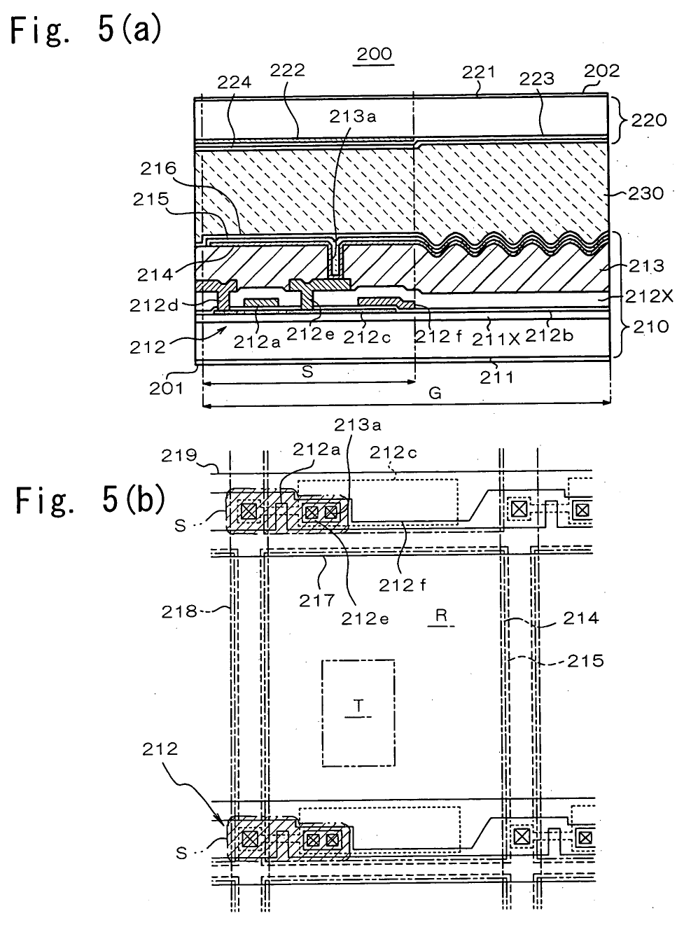

FIG. 5(a) is a schematic configuration schematic sectional view showing the rough structure of an liquid crystal display device 200 in the second exemplary embodiment, and FIG. 5(b) is a schematic layout plan view showing the two-dimensional structure of the element substrate 210. In this second exemplary embodiment, in place of the TFT 112 serving as the active element in the above-described first exemplary embodiment, a TFT 212 having a different structure is included. In this liquid crystal display device 200, an element substrate 210 is provided with a substrate 211, an insulating layer 213, a reflection layer 214, a transparent electrode 215, and an alignment layer 216, as in the above-described first exemplary embodiment. A facing-substrate 220 is provided with a substrate 221, a transparent electrode 223, and an alignment layer 224, as in the above-described first exemplary embodiment. Furthermore, polarizers 201 and 202 are disposed on the outer surfaces of the element substrate 210 and the facing-substrate 220, respectively.

Here, a light-shield film 222 covering the region for forming the above-described TFT 212 and the region between pixels is formed on the inner surface of the substrate 221. The TFT 212 is formed on the insulating film 211X disposed on the substrate 211. The insulating film 211X is a substrate layer to enhance the adhesion of the TFT 212 to the substrate 211 and to reduce or prevent the diffusion of impurities into a semiconductor layer 212c.

The TFT 212 of this liquid crystal display device 200 is provided with a gate 212a conductive-connected to a scanning line 217; an insulating thin film 212b formed from SiO₂ or the like, disposed thereunder; a semiconductor layer 212c composed of polysilicon or the like, including a portion (channel region) disposed as a layer under the gate 212a so as to face the gate 212a with the insulating thin film 212b therebetween; a source electrode 212d conductive-connected to a data line 218 and the source region of the semiconductor layer 212c; and a drain electrode 212e conductive-connected to the reflection layer 214, transparent electrode 215, and the drain region of the semiconductor layer 212c.

In the region adjacent to this TFT 212, the drain region of the semiconductor layer 212c is formed through extension, and a capacitor electrode 212f disposed facing this drain region with the insulating thin film 212b therebetween is included. This capacitor electrode 212f constitutes a storage capacitor together with the opposite drain region of the semiconductor layer 212c, and is composed of a part of a capacitor line 219. The interlayer insulation film 212X insulates the scanning line 217, the gate 212a, and the capacitor line 219 from the data line 218 in the thickness direction.

In this liquid crystal display device 200, as in the first exemplary embodiment described above, the element formation region S of the surface of the insulating layer 213 has a surface configuration different from that of the other surface region. Specifically, in the element formation region S, the surface of the insulating layer 213 is constructed to become flat, whereas a surface asperity shape as in the first exemplary embodiment is formed in the surface region other than the element formation region S. Therefore, the reflection layer 214 has a substantially flat reflection surface in the element formation region S, whereas a scattering reflection surface is formed in the surface region other than that and including the range in which the above-described storage capacitor is disposed. In the present exemplary embodiment, the electric field application structure region including not only the element formation region S, but also the wiring formation region, may be constructed to become flat, as described above, similarly to that in the first exemplary embodiment.

In order to form the above-described flat surface portion on the insulating layer 213, the mold surface of the mold may be constructed to become flat. Alternatively, the mold surface may be constructed to avoid contact with the surface of the insulating layer 213 in the asperity transfer. In particular, in the latter case, since substantially no transfer pressure is applied to the active element and wirings, defects in the active element and the wiring can be further reduced.

In the present exemplary embodiment, since the region (element formation region S) in which the reflection surface of the reflection layer 214 is constructed to become flat, is shielded against light by the light-shield film 222, the optical properties thereof cause no problem in display.

### THIRD EXEMPLARY EMBODIMENT

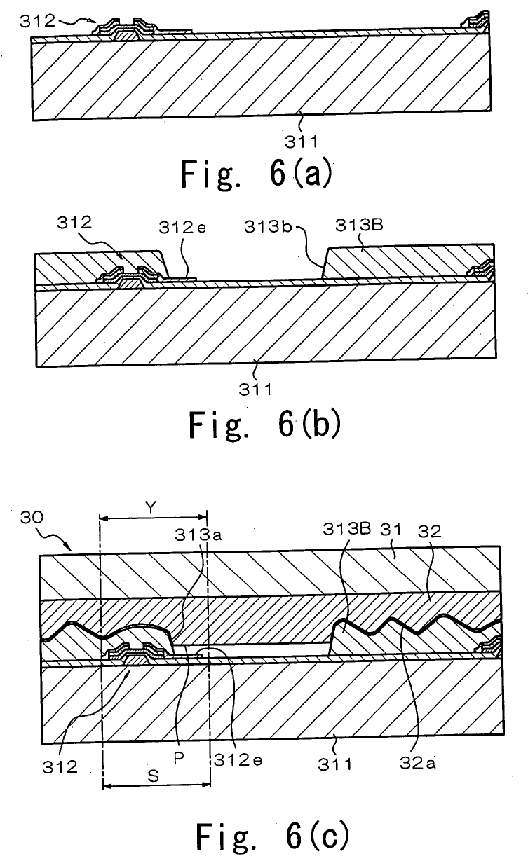

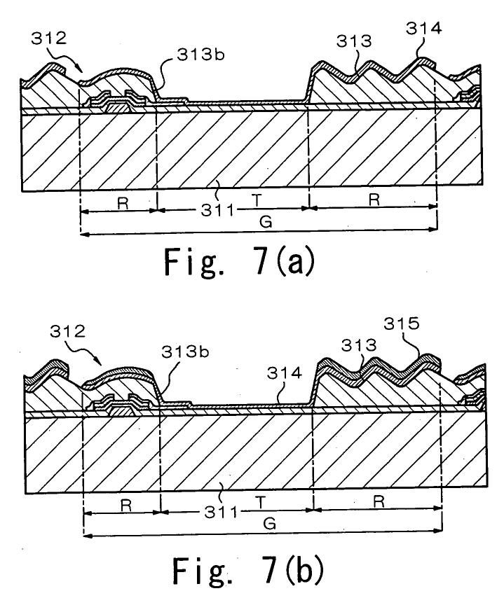

The third exemplary embodiment according to the present invention will be described with reference to FIG. 6 and FIG. 7. A liquid crystal display device of this third exemplary embodiment is different from the first exemplary embodiment only in the structure of an element substrate 310, and other configurations are similar to those in the first exemplary embodiment. Therefore, only the element substrate 310 will be described below.

With respect to the element substrate 310 of the present exemplary embodiment, as shown in FIG. 6(a), a TFT 312 is formed on a substrate 311 as in the first exemplary embodiment. Here, the structure and the manufacturing method of the TFT 312 is similar to those in the first exemplary embodiment and, therefore, the explanations thereof will not be provided.

As shown in FIG. 6(b), a photosensitive resin 313B having an aperture 313b is formed in a manner similar to that in the first exemplary embodiment. The aperture 313b of this photosensitive resin 313B is not formed simply as a contact hole, but is formed corresponding to the transmission region, in contrast to the first exemplary embodiment. That is, the aperture 313b is not formed simply in the contact hole portion constructed to expose a conductive junction (drain electrode 312e in the drawing) of the TFT 312, but is formed almost all over the transmission region. With respect to the aperture 313b shown in the drawing, the above-described contact hole portion and the portion disposed in the transmission region are constructed to be integrated.

As shown in FIG. 6(c), a fine asperity shape is transferred to the surface of the insulating layer 313B by the use of a mold 30 in a manner similar to that in the first exemplary embodiment. With respect to this asperity transfer step, since the point that the mold 30 is composed of a base 31 and a mold material 32 provided with a mold surface 32a and other points except for the following different points are similar to those in the first exemplary embodiment, the explanations thereof will not be provided.

In the mold 30 of the exemplary embodiment, since the aperture 313b is formed in the transmission region as well, the protrusion P is protruded over a wide range in accordance with the range of the aperture formed. The protrusion P may have a shape corresponding to the entire aperture 313b, as in the example shown in the drawing. However, the protrusion P may be constructed to become in the shape of, for example, a closed curve (in the shape of a soma) along the aperture edge of the aperture 313b. The protrusion P is constructed in order that the protrusion P is not brought into contact with the conductive junction of the active element during the transfer, as in the first exemplary embodiment.

As in the first exemplary embodiment, an avoidance surface portion Y is disposed at the portion corresponding to the element formation region S on the mold surface 32a of the mold 30 as well. This avoidance surface portion Y is constructed to become concave at the portion other than the portion corresponding to the range in which the aperture 313a is disposed (that is the portion in which the protrusion P is disposed) in the element formation region S. As a result, the avoidance surface portion Y is constructed in order that the transfer pressure applied to the active element (TFT 312) during the transfer is reduced. The insulating layer 313B provided with the asperity shape by the transfer is fired as in the first exemplary embodiment and, thereby, the insulating layer 313 is produced.

As shown in FIG. 7(a), a transparent electrode 314 similar to that in the first exemplary embodiment is formed on the surface of the insulating layer 313. This transparent electrode is formed not only on the surface of the insulating layer 313, but also on the inner bottom of the aperture 313b (on the surface of the substrate 311 and the insulating thin film).

Finally, as shown in FIG. 7(b), a reflection layer 315 similar to that in the first exemplary embodiment is formed on the surface of the portion, which is formed on the insulating layer 313, of the transparent electrode 314. This reflection layer 315 is not formed on the inner bottom of the aperture 313b. In this manner, the region in which the reflection layer 315 is formed becomes the reflection region R, and the region in which the reflection layer 315 is not formed becomes the transmission region T, in the pixel G.

In the present exemplary embodiment, since the insulating layer 313 is not disposed in the transmission region T, the insulating layer 313 can be composed of a coloring material or a light-shield material. Even in the case where the insulating layer 313 having transparency to some extent is used, there is an advantage that the light transmittance ratio of the transmission region T can be further increased. Furthermore, in the present exemplary embodiment, since a height difference corresponding to the thickness of the insulating layer 313 is formed between the transmission region T and the reflection region R, the thickness of the liquid crystal layer can be configured in order that the thickness becomes large in the transmission region T and the thickness becomes small in the reflection region R, through the use of this height difference. When such a multi-gap structure is adopted, the brightness of the transmissive display and the reflective display can become mutually compatible at a higher level.

In the above-described exemplary embodiment, the transparent electrode 314 is formed as a layer under the entire reflection layer 315. However, since it is essential only that the reflection layer 315 is conductive-connected to the transparent electrode 314, the transparent electrode 314 is not necessarily formed as the layer under the entire reflection layer 315. As in the first exemplary embodiment, the reflection layer may be formed initially on the insulating layer 313 and, thereafter, the transparent electrode may be formed. Conversely, in the above-described first exemplary embodiment, the transparent electrode may be formed initially and, thereafter, the reflection layer may be formed, as in the present exemplary embodiment. Furthermore, other items listed in the above-described first exemplary embodiment, for example, the configuration shown in FIG. 5, can be similarly adopted in this third exemplary embodiment.

### FOURTH EXEMPLARY EMBODIMENT

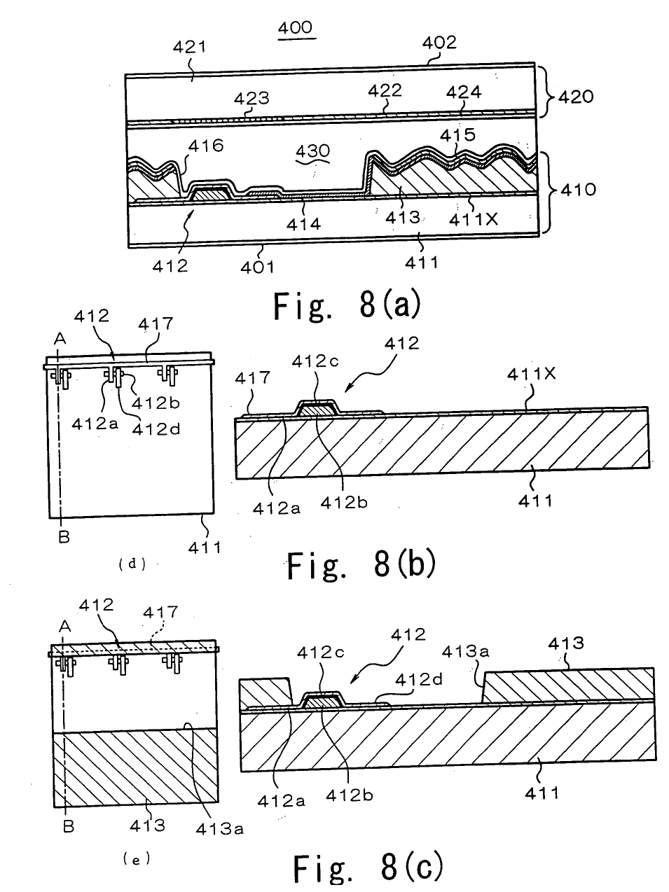

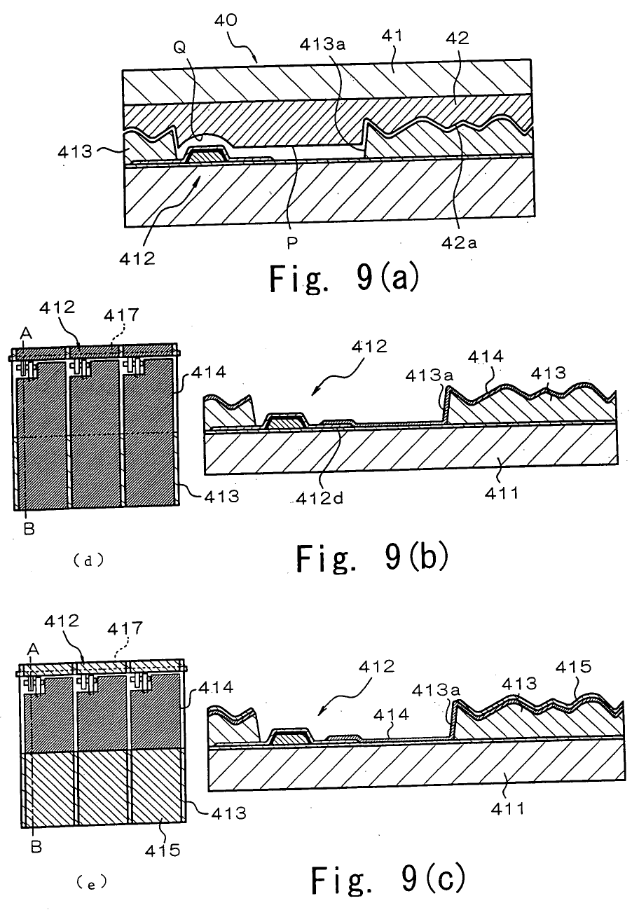

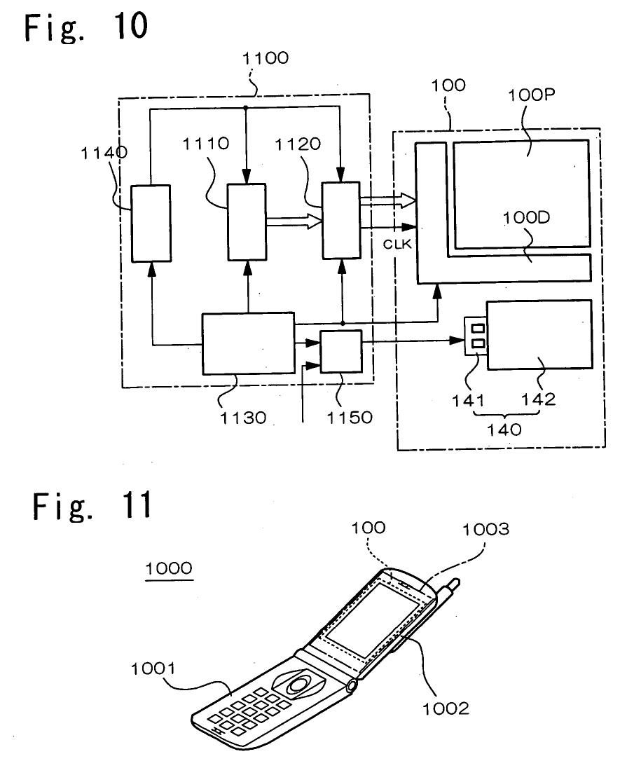

A liquid crystal display device of the fourth exemplary embodiment according to the present exemplary invention will be described with reference to FIG. 8 and FIG. 9. As shown in FIG. 8(a), the liquid crystal display device 400 of the present exemplary embodiment is an electro-optical device including a TFD (Thin Film Diode) as an active element. This liquid crystal display device 400 is constructed by disposing a liquid crystal 430 between an element substrate 410 and a facing-substrate 420, and is provided with polarizers 401 and 402 as in each of the above-described exemplary embodiments.

The element substrate 410 is provided with a substrate 411, a TFD 412 serving as an active element, an insulating layer 413, a transparent electrode 414, a reflection layer 415, and an alignment layer 416. Here, those other than the TFD 412 are composed of raw materials basically similar to the raw materials in the above-described exemplary embodiment.

On the other hand, the facing-substrate 420 is composed of a substrate 421, a plurality of transparent electrodes 422 disposed in the shape of stripes on this substrate 421, light shield films 423 disposed between the transparent electrodes 422, and an alignment layer 424. The present exemplary embodiment is different from each of the above-described exemplary embodiments in the point that the transparent electrodes 422 are constructed in the shape of bands extending in the direction perpendicular to the drawing shown in FIG. 8(a).

The TFD 412 includes a two-terminal nonlinear element having a MIM (Metal Insulator Metal) structure. This TFD 412 is disposed on a substrate layer 411X disposed on the substrate 411. This substrate layer 411X enhances the adhesiveness between the substrate 411 and the TFD 412, and is composed of, e.g., Ta₂O₅ formed by a method in which, for example, a Ta layer is formed and, thereafter, an oxidation treatment is performed. As shown in FIGS. 8(d) and 8(b), the TFD 412 including a first electrode layer 412a connected to a wiring 417, a second electrode layer 412b connected to this first electrode layer 412a with an insulating thin film 412c therebetween, and a third electrode layer 412d connected to this second electrode layer 412b with an insulating thin film 412c therebetween, is formed on the substrate layer 411X.

With respect to more specific manufacturing procedure, for example, the second electrode layer 412b is formed from a metal, e.g., Ta, by a vapor deposition method, a sputtering method, or the like, and the surface thereof is oxidized by an anodization method, so that the above-described insulating thin film 412c composed of Ta₂O₅ is formed. Subsequently, a film of a metal, e.g., Cr, is formed by the vapor deposition method, the sputtering method, or the like on the second electrode layer 412b covered with this insulating thin film 412c, so that the above-described first electrode layer 412a and the third electrode layer 412d are formed.

The above-described TFD 412 is constructed by one pair of two-terminal nonlinear elements being connected in series, each element having the MIM structure in which different types of metal are joined with the insulating thin film 412c therebetween. The publicly known symmetry of the potential polarity in the nonlinear characteristics of the TFD 412 can be addressed or achieved by symmetrically constructing the junction structure of different types of metal, as described above.

As shown in FIGS. 8(e) and 8(c), application of a photosensitive resin, pre-baking, if necessary, and formation of an aperture 413a by exposure and development are performed sequentially and, thereby, an insulating layer 413 having the aperture 413a is formed, as in the above-described exemplary embodiment. Here, in the present exemplary embodiment, the aperture 413a is formed in order that a conductive junction (third electrode layer 412d) of the active element (TFD 412) is exposed. However, the aperture 413a is constructed not only to expose the above-described conductive junction, but also to include the region to become the transmission region as well. Furthermore, the aperture 413a is constructed to expose a portion (MIM structure portion) of the active element (TFD 412) as well, the portion performing the switching function. In particular, the aperture 413a is formed in order that all the portion to expose the above-described conductive junction, the transmission region, and the portion to perform the switching function of the active element are constructed integrally in the present exemplary embodiment.

As shown in FIG. 9(a), a fine asperity shape is transferred to the surface of the insulating layer 413 by the use of a mold 40. The transferring method in this asperity transfer is similar to that in each of the above-described exemplary embodiments. The mold 40 including a base 41 and a mold material 42 provided with a mold surface 42a is substantially similar to that in the above-described third exemplary embodiment as well. Here, a protrusion P is formed at the portion of the mold surface 42a, the portion corresponding to the aperture 413a. In this manner, when the mold 40 is applied, a state in which the protrusion P supports the aperture edge of the aperture 413a from the inside is brought about. In the present exemplary embodiment, a concave portion Q is disposed at a part of the protrusion P in order to avoid the element formation region. As described above, the protrusion P is constructed in order that the end thereof is not brought into contact with the active element and the inner bottom of the aperture 413a during the transfer.

As shown in FIGS. 9(d) and 9(b), a transparent electrode 414 similar to that in each of the above-described exemplary embodiments is formed to overlap the third electrode layer 412d. Here, the transparent electrode 414 is formed almost all over the entire pixel from the inner bottom of the aperture 413a to the surface of the insulating layer 413.

As shown in FIGS. 9(e) and 9(c), a reflection layer 415 is formed on the transparent electrode 414. Here, the reflection layer 415 is formed only on the surface of the insulating layer 413, and is not formed on the inner bottom of the aperture 413a. That is, the portion at which the insulating layer 413 is disposed becomes the reflection region on which the reflection layer 415 is disposed, and the portion at which the insulating layer 413 is not disposed becomes the transmission region because the reflection layer 413 is not disposed.

In the present exemplary embodiment, the aperture 413a of the insulating layer 413 is formed to expose a portion (MIM structure portion) of the active element (TFD 412) as well, the portion performing the switching function. Consequently, the transfer pressure is not applied to the portion to perform the switching function during the following asperity transfer. Therefore, the active element can be reduced or prevented from being damaged.

In the above-described exemplary embodiment, the transparent electrode 414 is formed as a layer under the entire reflection layer 415. However, the transparent electrode 414 is not necessarily formed as the layer under the entire reflection layer 415 as long as the reflection layer 415 is conductive-connected to the transparent electrode 414. As in the first exemplary embodiment, the reflection layer may be formed initially on the insulating layer 413 and, thereafter, the transparent electrode may be formed.

Furthermore, an insulating layer having an aperture similar to that in this fourth exemplary embodiment (that is, the aperture which exposes the element formation region as well) can be adopted in the element substrate including the TFT serving as the active element (the configuration shown in FIG. 5 is included.) described in the first exemplary embodiment to the third exemplary embodiment.

### FIFTH EXEMPLARY EMBODIMENT

Finally, electronic equipment including the electro-optical device according to the above-described exemplary embodiment will be described with reference to FIG. 10 and FIG. 11 as the fifth exemplary embodiment according to the present invention. In the present exemplary embodiment, electronic equipment provided with the above-described liquid crystal display device 100 as the display device will be described. However, other exemplary embodiments can be applied to the present exemplary embodiment as in the liquid crystal display device 100.

FIG. 10 is a schematic configuration diagram showing the entire configuration of a control system (display control system) with respect to the liquid crystal display device 100 of the electronic equipment according to the present exemplary embodiment. The electronic equipment shown here has a display control circuit 1100 including a display information output source 1110, a display information processing circuit 1120, a power supply circuit 1130, a timing generator 1140, and a light source control circuit 1150. The above-described liquid crystal display device 100 is provided with a liquid crystal display panel 100P having the above-described configuration and a driving circuit 100D to drive this liquid crystal display panel 100P. This driving circuit 100D can also be constructed by an electronic component (semiconductor IC or the like) directly mounted on the liquid crystal display panel 100P, a circuit pattern disposed on the panel surface, a semiconductor IC chip or a circuit pattern mounted on a circuit substrate conductive-connected to the liquid crystal panel, or the like. Furthermore, the liquid crystal display device 100 is provided with a backlight 140 disposed at the rear of the above-described liquid crystal display panel 100P.

The display information output source 1110 is provided with memory composed of ROM (Read Only Memory), RAM (Random Access Memory), or the like, a storage unit composed of magnetic recording disk, optical recording disk, or the like, and a tuning circuit to perform tuning and output of digital image signals, and is configured to supply the display information in the form of image signals and the like in a predetermined format to the display information processing circuit 1120 based on various clock signals generated by the timing generator 1140.

The display information processing circuit 1120 is provided with various known circuits, e.g., a serial-parallel converter, an amplifying and inverting circuit, a rotation circuit, a gamma correction circuit, and a clamping circuit, performs processing of the input display information, and supplies the image information together with clock signals CLK to the driving circuit 100D. The driving circuit 100D includes a scanning line driving circuit, a signal line driving circuit, and an inspection circuit. The power supply circuit 1130 supplies predetermined respective voltages to the above-described constituents.

The light source control circuit 1150 supplies an electric power supplied from the power supply circuit 1130 to the light source portion 141 of the backlight 140 based on the control signals introduced from the outside. The light emitted from the light source portion 141 is incident into a light guide plate 142, and is applied from the light guide plate 142 to the liquid crystal display panel 100P. This light source control circuit 1150 controls lighting/non-lighting of each light source of the light source portion 141 in accordance with the above-described control signals. Furthermore, the luminance of each light source can also be controlled.

FIG. 11 shows an appearance of a mobile phone as an exemplary embodiment of electronic equipment according to exemplary embodiments of the present invention. This electronic equipment 1000 includes a control portion 1001 and a display portion 1002, and a circuit substrate 1003 is disposed in the inside of the cabinet of the display portion 1002. The above-described liquid crystal display device 100 is mounted on the circuit substrate 1003. In the configuration, the display screen of the above-described liquid crystal panel 100P can be visually identified on the surface of the display portion 1002.

The electro-optical device with a sounding body and the electronic equipment are not limited to the above-described exemplary examples shown in the drawings. As a matter of course, various exemplary modifications can be made within the scope of exemplary embodiments of the present invention. For example, in each of the above-described exemplary embodiments, the insulating layer having the aperture is formed by photolithography through the use of the photosensitive resin. However, exemplary embodiments of the present invention are not limited to the above-described insulating layer, and insulating layers composed of not only the resin raw materials, but also various insulating raw materials, e.g., inorganic oxides, can be used. With respect to the method for providing the aperture in the insulating layer, various methods, e.g., an etching method, a laser boring method, and a screen printing method, can be used.

1. A method for manufacturing an electro-optical device in which a pair of substrates are disposed facing each other with an electro-optical layer therebetween and an active element and a reflection layer are provided on one substrate of the pair of substrates, the method comprising:
forming the active element on the one substrate;
forming an insulating layer on the one substrate provided with the active element, the insulating layer having an aperture reaching a conductive junction of the active element;
forming an asperity shape through transfer on the surface of the insulating layer by pressing a mold against the insulating layer having the aperture; and
forming the reflection layer on the insulating layer in order that a scattering reflection surface incorporating the asperity shape is provided and, conductive-connecting an electrode constructed by one of the reflection layer and separately from the reflection layer, to the active element via one of directly and indirectly the aperture upper layer processing.

2. The method for manufacturing an electro-optical device according to claim 1, further including disposing a protrusion to be inserted into the aperture, disposed on a mold surface of the mold, at a location corresponding to the aperture.

3. The method for manufacturing an electro-optical device according to claim 1, further including disposing a concave portion lower than the surrounding, on a mold surface of the mold, at a location corresponding to the active element.

4. The method for manufacturing an electro-optical device according to claim 1, further including disposing the aperture in order that at least a portion of the active element is exposed, the portion performing the switching function.

5. The method for manufacturing an electro-optical device according to claim 1, further including disposing a transmission region not provided with the reflection layer, and the aperture including a portion formed corresponding to the transmission region.

6. The method for manufacturing an electro-optical device according to claim 1, the upper layer processing includes forming the reflection layer on the insulating layer and forming the electrode as a layer one of on and under the reflection layer, the electrode at least overlapping the reflection layer.

7. The method for manufacturing an electro-optical device according to claim 1, the insulating layer formation sequentially includes applying a photosensitive resin, exposing the photosensitive resin, and developing the photosensitive resin to form the aperture.

8. An electro-optical device, comprising:
a pair of substrates disposed facing each other;
an electro-optical layer between the pair of substrates;
an active element provided on one substrate of the pair of substrates; and
a reflection layer provided on one substrate of the pair of substrates,
an insulating layer having an aperture being disposed between the active element and the reflection layer,
the insulating layer having a surface asperity shape transferred by a mold being pressed against the insulating layer,
the reflection layer being provided with a scattering reflection surface incorporating the surface asperity shape, and
an electrode one of constructed by the reflection layer and constructed separately from the reflection layer being conductive-connected to a conductive junction of the active element via one of directly and indirectly the aperture.

9. The electro-optical device according to claim 8, the aperture being disposed in order that at least a portion of the active element is exposed, the portion performing the switching function.

10. The electro-optical device according to claim 8, a transmission region not provided with the reflection layer being disposed, and the aperture including a portion formed corresponding to the transmission region.

11. Electronic equipment, comprising:
the electro-optical device according to claim 8 in a display portion.
